(19) United States
(12) Patent Application Publication
(10) Pub. No.: US 2016/0163722 A1
(43) Pub. Date: Jun. 9, 2016

(54) NON-VOLATILE MEMORY CELL AND METHOD OF MANUFACTURING THE SAME

(71) Applicant: UNITED MICROELECTRONICS CORP., Hsin-Chu City (TW)

(72) Inventors: Yuan-Hsiang Chang, Hsinchu City (TW); Aaron Chen, Singapore (SG); JIANJUN YANG, Singapore (SG); Chih-Chien Chang, Hsinchu City (TW)

(21) Appl. No.: 14/596,227

(22) Filed: Jan. 14, 2015

(30) Foreign Application Priority Data
Dec. 4, 2014 (CN) 201410733497.8

(51) Int. Cl. H01L 27/115; H01L 29/66; H01L 21/321; H01L 21/28; H01L 21/02; H01L 21/3213; H01L 29/788; H01L 29/423

(52) U.S. Cl. CPC H01L 27/11521; H01L 29/788; H01L 29/66825; H01L 29/42328; H01L 29/42376; H01L 21/28273; H01L 21/02532; H01L 21/02595; H01L 21/32133; H01L 21/32139; H01L 21/3212; H01L 27/11526

(57) ABSTRACT

A non-volatile memory cell includes a substrate, an erase gate disposed on the substrate and having a top plane, two floating gates disposed respectively at both sides of the erase gate, two control gates disposed respectively on two floating gates, and two select gates disposed respectively at outer sides of the two floating gates, where the two select gates have tilted top planes which are symmetric to each other.

### BACKGROUND OF THE INVENTION

1. Field of the Invention

The present invention generally relates to a non-volatile memory cell, and more particularly, to a non-volatile memory cell with split gate and method of manufacturing the same.

2. Description of the Prior Art

Split gate non-volatile memory devices are well known in the art. For example, U.S. Pat. No. 7,927,994 discloses a split gate non-volatile memory cell, which is incorporated herein by reference for all purposes. FIG. 1 illustrates an example of such a split gate memory cell formed on a semiconductor substrate 12. Source and drain regions 16 and 14 are formed as diffusion regions in substrate 12, and define a channel region 18 therebetween. The memory cell includes four conductive gates: a floating gate 22 disposed over and insulated from a first portion of the channel region 18 and a portion of the source region 16, a control gate 26 disposed over and insulated from the floating gate 22, an erase gate 24 disposed over and insulated from the source region 16, and a select gate 20 disposed over and insulated from a second portion of the channel region 18. A conductive contact 10 can be formed to electrically connect to the drain region 14. In this type of memory cell, the select gate 20 is a single conductive line (usually referred as a word line) which corresponds to a row of memory cells and may extend through multiple columns of the memory cells.

In conventional method, the select gate 20 is formed by first forming a poly-silicon layer and then performing a photo-lithographic process. However, when using this standard method to manufacture two symmetric select gates, the two select gates would have different widths due to inevitable misalignment in the photo-lithographic process, thereby impacting the electrical performance of the memory cells. This problem would become progressively worse when the size of the device is getting smaller. Accordingly, there is a need in the industry to improve current process for manufacturing two select gates in order to solve this problem.

### SUMMARY OF THE INVENTION

To solve the above-mentioned conventional problem, the present invention provides a novel method of manufacturing a memory cell, wherein a conformal poly-silicon layer and a blanket etch process are applied to replace conventional photolithographic process and form select gates (i.e. word lines), thereby effectively avoiding the overlay shift problem in the photolithographic process. The widths of two select gates may be more precisely controlled to improve the electrical performance.

One objective of the present invention is to provide a non-volatile memory cell including a substrate, an erase gate with a top plane disposed on the substrate, two floating gates disposed respectively at two outer sides of the erase gate, two control gates disposed respectively on the two floating gates, and two select gates disposed respectively at outer sides of the two floating gates, wherein the two select gates have tilted top plane which are symmetric to each other.

Another objective of the present invention is to provide a method of manufacturing a non-volatile memory cell, which includes the steps of: providing a substrate; forming two stack structures on the substrate, wherein each stack structure has a floating gate and a control gate; forming a conformal poly-silicon layer on the substrate and two stack structures; performing a blanket etch process to remove a predetermined thickness of the poly-silicon layer, thereby forming two select gates respectively at outer sides of the two control gates, wherein the two select gates have tilted top planes which are symmetric to each other; forming a cap oxide layer on the substrate and two select gates which exposes the poly-silicon layer between the two stack structures; and performing an etch process on the poly-silicon layer between the two stack structures with the cap oxide layer as an etch mask to form an erase gate between the two control gates.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 is a cross-sectional view schematically depicting a split gate type non-volatile memory cell in prior art.

FIGS. 2-10 are cross-sectional views schematically depicting an exemplary process flow of manufacturing a split gate type non-volatile memory cell in accordance with the embodiment of the present invention.

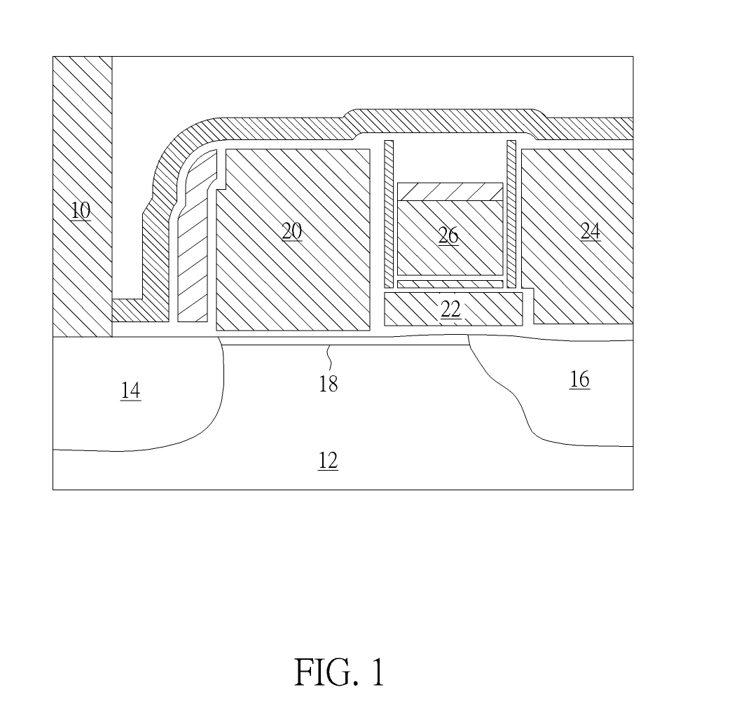

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

Before describing the preferred embodiment in more detail, further explanation shall be given regarding certain terms that may be used throughout the descriptions.

The term “etch” or “etching” is used herein to generally describe a fabrication process of patterning a material, such that at least a portion of the material remains after the etch is completed. For example, it should be understood that the process of etching silicon involves the steps of patterning a masking layer (e.g., photoresist or a hard mask) above the silicon, and then removing the areas of silicon no longer protected by the masking layer. As such, the areas of silicon protected by the mask would remain behind after the etch process is complete. However, in another example, etching may also refer to a process that does not use a mask, but still leaves behind at least a portion of the material after the etch process is complete. The above description serves to distinguish the term “etching” from “removing.” When etching a material, at least a portion of the material remains behind after the process is completed. In contrast, when removing a material, substantially all of the material is removed in the process. However, in some embodiments, ‘removing’ is considered to be a broad term that may incorporate etching.

During the descriptions herein, various regions of the substrate upon which the field-effect devices are fabricated are mentioned. It should be understood that these regions may exist anywhere on the substrate and furthermore that the regions may not be mutually exclusive. That is, in some embodiments, portions of one or more regions may overlap. Although up to three different regions are described herein, it should be understood that any number of regions may exist on the substrate and may designate areas having certain types of devices or materials. In general, the regions are used to conveniently describe areas of the substrate that include similar devices and should not limit the scope or spirit of the described embodiments.

The terms “forming,” “form,” “deposit,” or “dispose” are used herein to describe the act of applying a layer of material to the substrate. Such terms are meant to describe any possible layer-forming technique including, but not limited to, thermal growth, sputtering, evaporation, chemical vapor deposition, epitaxial growth, electroplating, etc. According to various embodiments, for instance, deposition may be performed according to any appropriate well-known method. For instance, deposition can comprise any process that grows, coats, or transfers material onto a substrate. Some well-known technologies include physical vapor deposition (PVD), chemical vapor deposition (CVD), electrochemical deposition (ECD), molecular beam epitaxy (MBE), atomic layer deposition (ALD), high density plasma CVD (HDPCVD) and plasma-enhanced CVD (PECVD), amongst others.

The “substrate” as used throughout the descriptions is most commonly thought to be silicon. However, the substrate may also be any of a wide array of semiconductor materials such as germanium, gallium arsenide, indium phosphide, etc. In other embodiments, the substrate may be electrically non-conductive such as a glass or sapphire wafer.

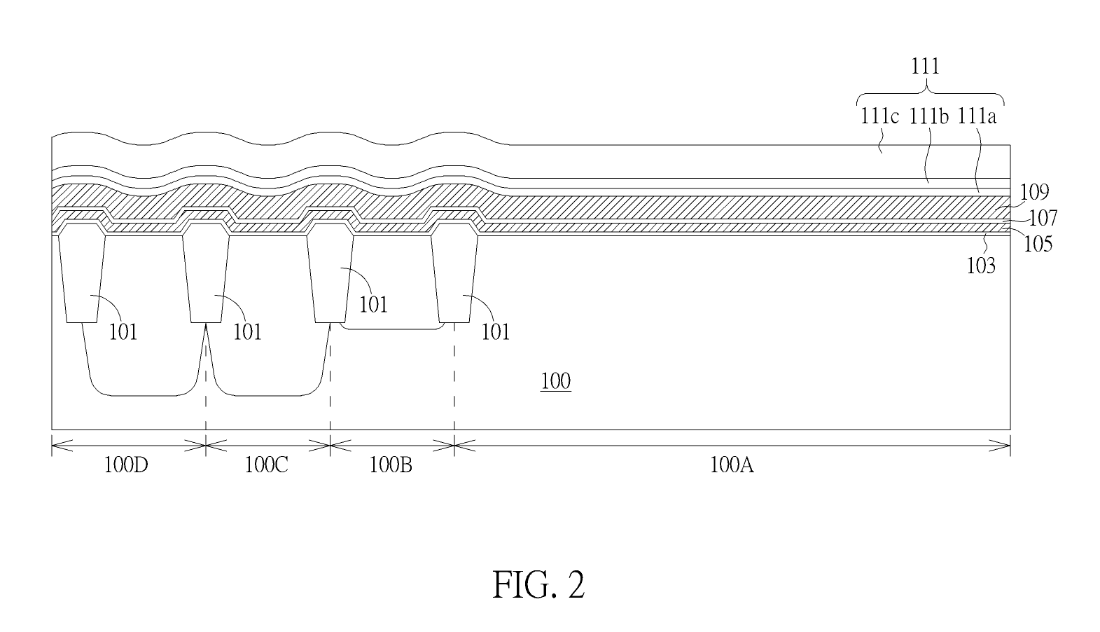

FIGS. 2-10 are cross-sectional views schematically depicting an exemplary process flow of manufacturing a split gate type non-volatile memory cell in accordance with the embodiment of the present invention. First, please refer to FIG. 2. The non-volatile memory cell/device of the present invention starts from a semiconductor substrate 100, for example, a silicon wafer. The substrate 100 is usually a p-type semiconductor substrate, or a substrate with predefined p-type well, while the later-doped source/drain region is n-type. Alternatively, the substrate 100 may be n-type semiconductor substrate with doped p-type source/drain regions.

As shown in FIG. 2, in the preferred embodiment of the present invention, the substrate 100 is defined into several areas 100A, 100B, 100C and 100D which are respectively for semiconductor devices of different types to be disposed thereon. Area 100A is a memory (device) area used for the non-volatile memory cells of the present invention, such as the components of a memory cell likes select gate (SG), floating gate (FG), control gate (CG) and erase gate (EG). This area will be the subject in the description of the structure and method of the present invention. The areas other than the memory area 100A on the substrate 100 may include the area for forming logic control circuits. For example, the area 100B and area 100C are high-voltage (HV) areas with a p-well and an n-well respectively. The area 100D is low-voltage (LV) area with combined p-well and n-well. The areas 100A, 100B, 100C and 100D, or all kinds of the semiconductor device formed thereon, are divided by preformed shallow trench isolations (STI) 101. Please note that, for the simplicity of the drawings, only one semiconductor device will be demonstrated in the area of each type in each following figures to explain the process of the present invention.

Please refer again to FIG. 2. A first silicon oxide layer 103, a first poly-silicon layer 105, a second silicon oxide layer 107, a second poly-silicon layer 109, and an insulating layer 111 (ex. a tri-layer of silicon oxide 111a/silicon nitride 111b/silicon oxide 111c, ONO) are sequentially formed on the substrate 100. In the preferred embodiment of the present invention, the first poly-silicon layer 105 is the material layer for the floating gate to be formed in the following process, the second poly-silicon layer 109 is the material layer for the control gate to be formed in the following process, and the insulating layer 111 serves as a hard mask.

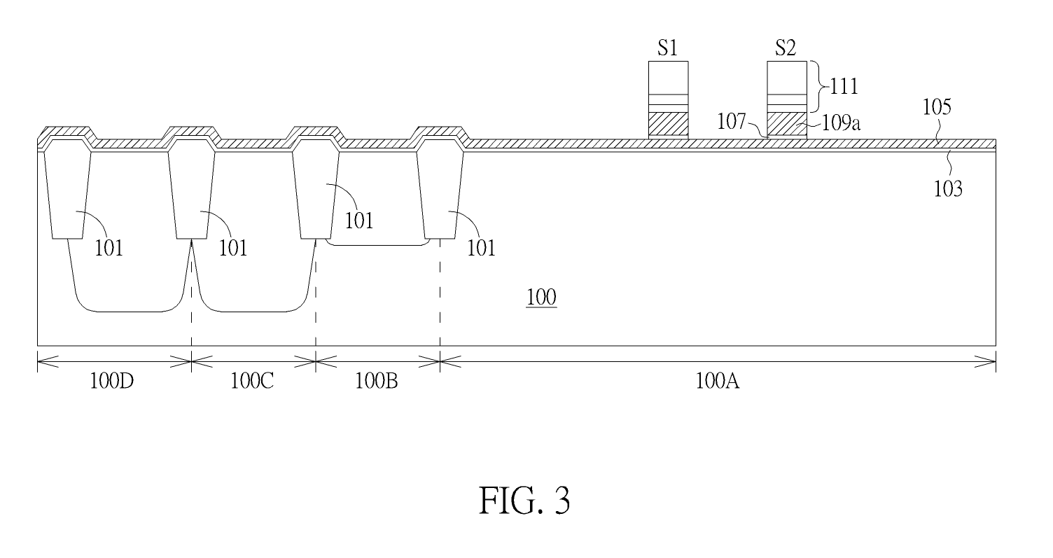

Please refer to FIG. 3. In this step, the second silicon oxide layer 107, the second poly-silicon layer 109 and the insulating layer 111 formed in previous step are patterned into two stack structures S1 and S2. The patterning step may include but is not limited to the steps of: depositing a photoresist on the insulating layer 111 and performing an exposure and development processes to define the photoresist with predetermined patterns (not shown); performing an anisotropic dry etch process with the patterned photoresist as an etch mask to etch the unshielded second silicon oxide layer 107, the second poly-silicon layer 109 and the insulating layer 111 until the underlying first poly-silicon layer 105 is exposed. In the preferred embodiment, this step defines the control gate 109a pattern on the floating gate. Please note that, although only two stack structures S1 and S2 are demonstrated in FIG. 3 to represent the two control gates included in single split gate type non-volatile memory cell, those ordinarily skilled in the art should clearly know from the drawings that there may be numerous ones of this kind of stack structures divided from each other on the memory area 100A.

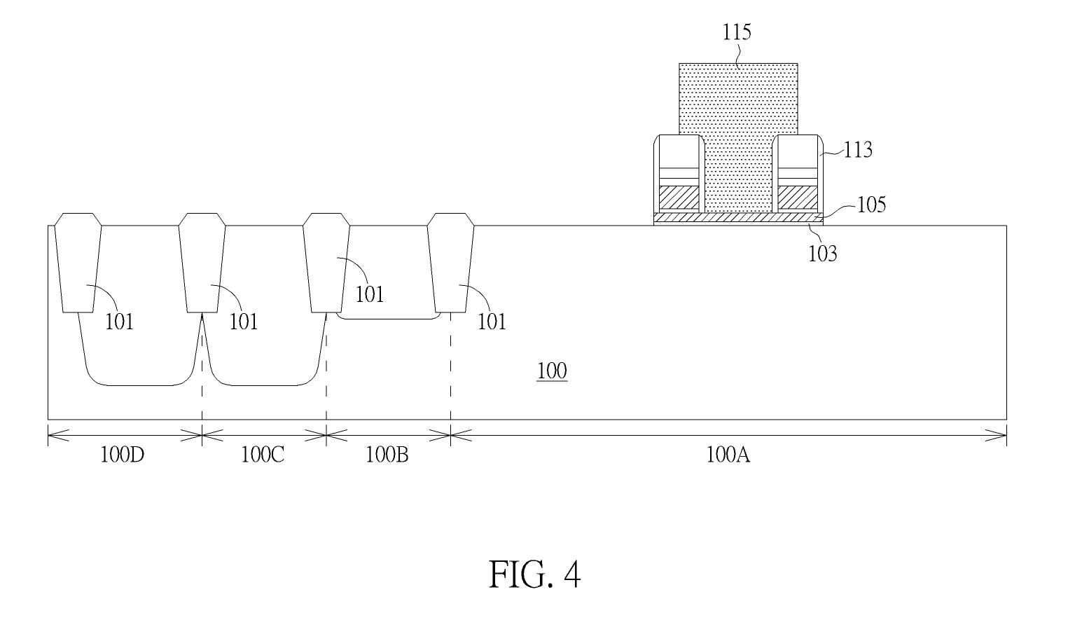

Please refer to FIG. 4. After the stack structures S1 and S2 are formed, a spacer 113 is formed around the stack structures S1 and S2. The steps of forming the spacer 113 include but are not limited to: conformally depositing a silicon oxide layer and a silicon nitride layer on the stack structures S1 and S2; and performing an anisotropic etch process on etch the silicon oxide layer and the silicon nitride layer to form a bilayer spacer 113 with silicon oxide and silicon nitride.

Refer again to FIG. 4. After the spacer 113 is formed, a photoresist 115 is formed on the region (referred hereinafter as an inner region) between the two stack structures S1 and S2. The photoresist 115 would cover the inner region and a portion of nearby stack structures S1 and S2. Subsequently, an anisotropic etch process is performed on the underlying first silicon oxide layer 103 and first poly-silicon layer 105 with the photoresist 115 and two stack structures S1 and S2 as an etch mask. The resulting structure is shown in FIG. 4. This step preliminarily defines the region of every split gate type non-volatile memory cell on the memory area 100A. The inner region between the stack structures S1 and S2 is the area predetermined to form an erase gate. Please note that this step also removes the first silicon oxide layer 103 and first poly-silicon layer 105 in other areas.

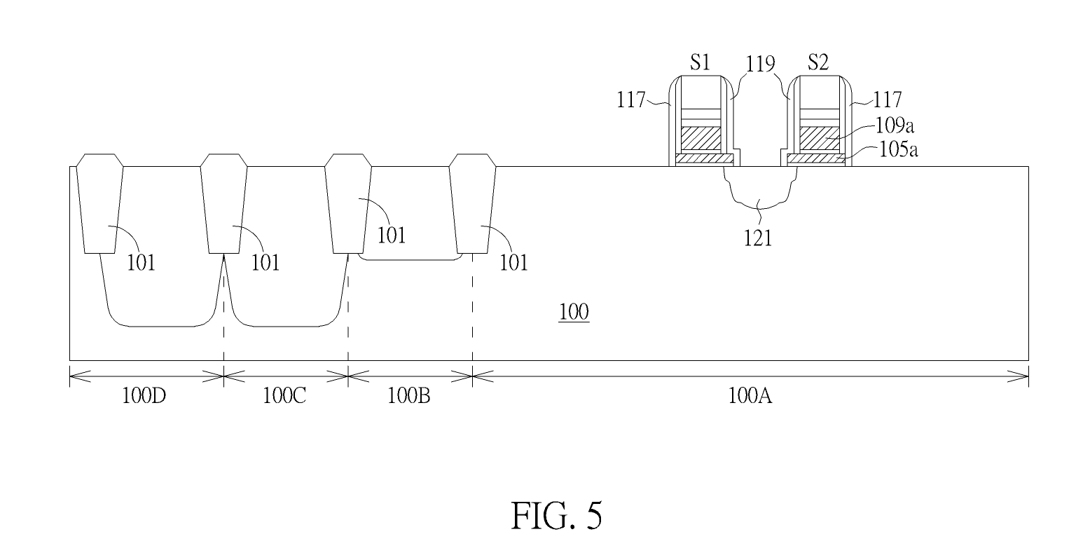

Please refer to FIG. 5. In this step, first form another spacer 117 on the outer sidewalls of the stack structures S1 and S2 after removing the photoresist 115. The spacer 117 may be silicon oxide which is formed by the same method as the previous spacer. Subsequently, remove the first silicon oxide layer 103 and the first poly-silicon layer 105 between the stack structures S1 and S2. The removing step may include but are not limited to the steps of: form a photoresist (not shown) on the substrate 100 and the stack structures S1 and S2 and expose the inner region between the stack structures S1 and S2; and perform an anisotropic etch process to remove the first silicon oxide layer 103 and the first poly-silicon layer 105 in the inner region and expose the underlying substrate 100 surface. This step defines the pattern of two floating gates 105a of the split gate type non-volatile memory cell in the present invention. Please note that in this preferred embodiment, the width of floating gate 105a is wider than the width of the control gate 109a, but is not limited thereto.

Please refer again to FIG. 5. After the floating gates 105a are defined, perform a high pressure ion implantation process to form a common source region (line) 121 in exposed substrate 100. Subsequently, form another spacer 119 on the inner sidewalls of the stack structures S1 and S2. In the preferred embodiment of the present invention, the spacer 119 will serve as an insulating layer between the floating gate 105a, control gate 109, and the erase gate to be formed in later process. In this way, after the stack structures S1 and S2 with the floating gate (FG) and the control gate (CG) are completed, it is clearly shown in the figures that the stack structures S1 and S2 are substantially symmetric to each other.

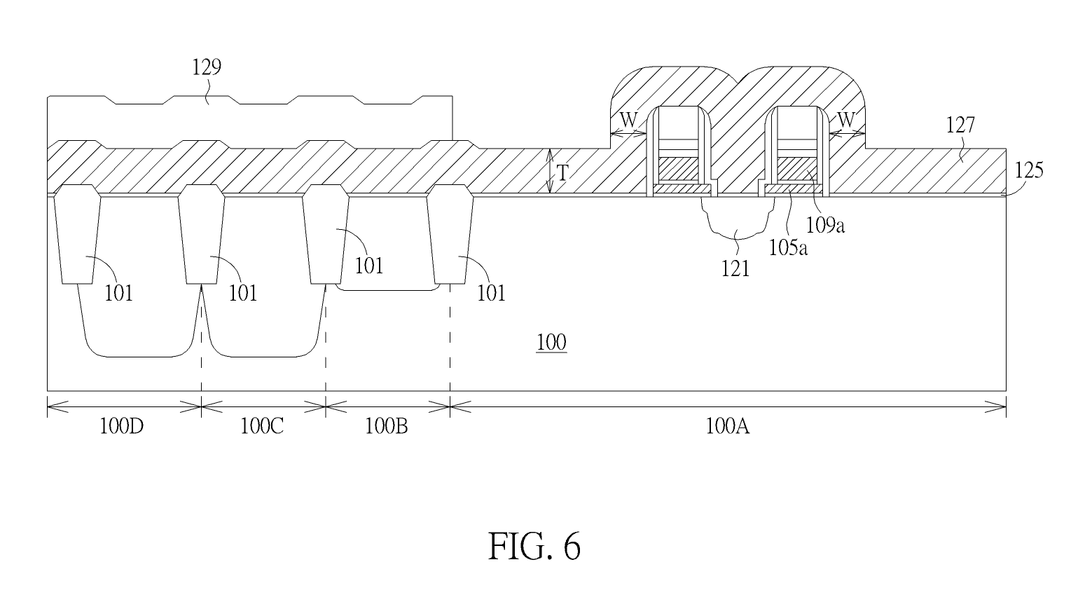

The select gate (SG) and erase gate (EG) of the memory cell are then made in the following process. Please refer to FIG. 6. First, form a thin oxide layer 125 on the surface of exposed substrate 100. The oxide layer 125 will serve as a gate oxide layer of the devices in various areas, for example, the gate oxide layer between the substrate 100 and the select gate of the memory cell in memory area 100A, wherein the gate oxide layer 125 may have different thickness corresponding to different type areas and devices on the substrate. In next the step, deposit a poly-silicon layer 127 on the oxide layer 125 and the stack structures S1 and S2. In the preferred embodiment of the present invention, the poly-silicon layer 127 serves concurrently as the material layers for the gate of the circuit devices in the logic area and the select gate of the memory devices in the memory area.

Please note that in the present invention, the poly-silicon layer 127 is formed by conformal deposition. This means the poly-silicon layer 127 would have substantially uniform thickness, for example, a thickness Ton the substrate surface. More particularly, the poly-silicon layer 127 on the outer sidewalls of the stack structures S1 and S2 would also have uniform width W. This is the important factor why the self-alignment may be achieved to obtain the two select gates with equal widths in the following processes of the present invention, and the resulting poly-silicon layer 127 would fill up the inner region between the stack structures S1 and S2.

In next the step, since the two select gates of the memory cell will be formed by the unique method provided by the present invention, the gate structures in memory area 100A and logic areas 100B/100C/100D should be made respectively in different processes. First, form a cap oxide layer 129 on the conformal poly-silicon layer 127 in the logic areas 100B/100C/100D. This may avoid the poly-silicon layer 127 on the logic areas 100B/100C/100D being influenced by the processes for the memory area 100A. The steps of forming this cap oxide layer 129 may include but are not limited to: form an oxide material layer on entire poly-silicon layer 127, perform a photolithographic process to remove the oxide material layer on memory area 100A.

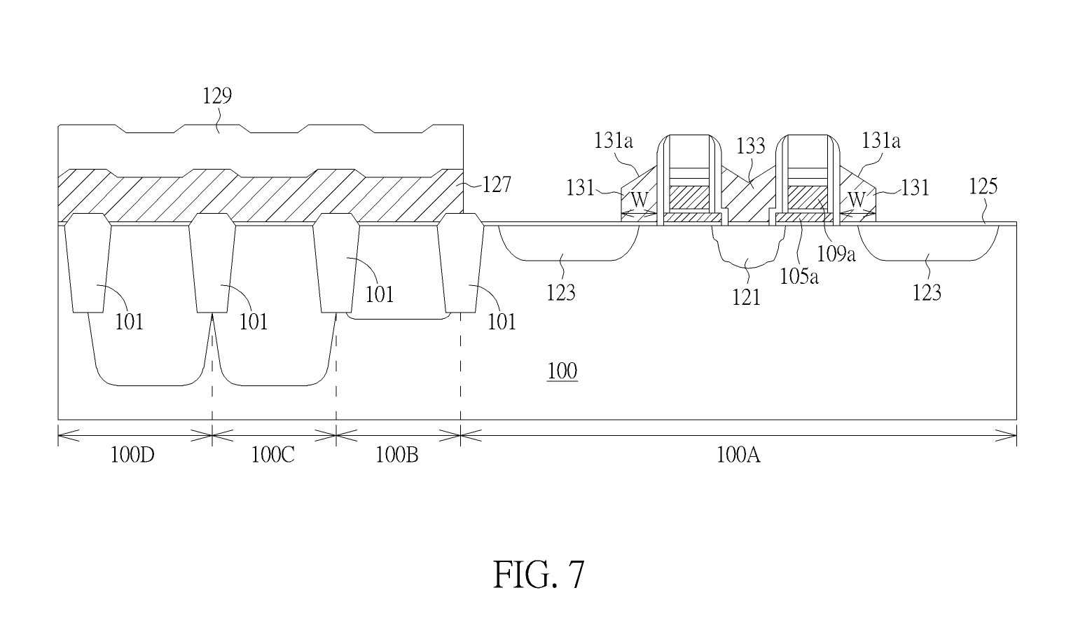

Please refer to FIG. 7. In this step, perform a blanket etch process on the poly-silicon layer 127 with the above-mentioned cap oxide layer 129 as an etch mask. The feature of the blanket etch process is that it can remove a predetermined vertical thickness of exposed target layer on the substrate. In the preferred embodiment of the present invention, as shown in FIG. 7, the blanket etch process would completely remove a thickness T of the poly-silicon layer 127 on the top surface of the stack structures S1 and S2. Since the vertical thickness of the poly-silicon layer 127 on the outer sidewalls of the stack structures S1 and S2 is far thicker than the thickness T of the poly-silicon layer 127 on the substrate or the top surface of the stack structures, the trapezoidal poly-silicon structures as shown in the figure will be formed in a self-alignment fashion after this etch process. The trapezoidal poly-silicon structure is the select gate (i.e. the word line, WL) 131 of the memory cell in the present invention. There will be poly-silicon structure 133 remaining in the inner region between the stack structures S1 and S2 to serve as the material layer for the erase gate to be formed in the following process.

Please refer again to FIG. 7. In the preferred embodiment of the present invention, since the select gate 131 is formed from the conformal poly-silicon layer 127 and is subject to blanket etching, the two select gates 131 would have tilted top planes 131a which are symmetric to each other. Furthermore, since the horizontal thickness of the poly-silicon layer 127 is not influenced by the blanket etch process, the width of resultant select gate 131 would remain unchanged as the horizontal width W of the poly-silicon layer 127, thereby achieving the purpose of more precisely controlling the widths of two select gates by self-alignment method of the present invention.

After the select gates are made, in next step, perform a high pressure ion implantation process to form drain regions 123 (also referred as doped word line regions) respectively in the substrate 100 outside the two stack structures S1 and S2. The regions between the source region 121 and drain regions 123 are channel regions.

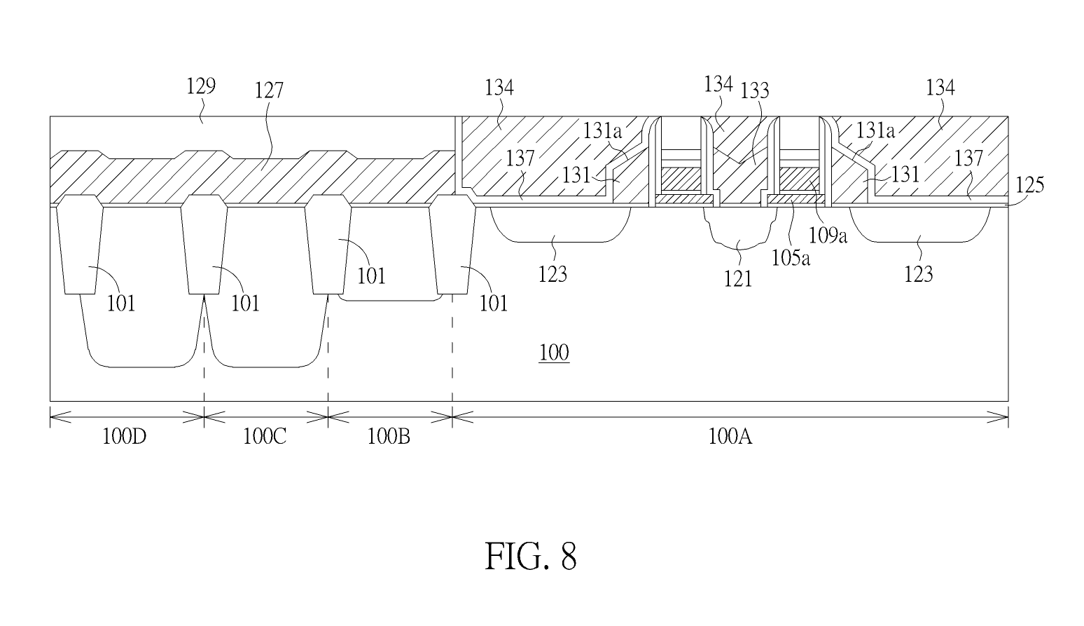

In next step, the erase will be made after the select gates and the drain regions are completed. Please refer now to FIG. 8. In the preferred embodiment of the present invention, the erase is formed from the poly-silicon structure 133 remaining in the inner region between the stack structures S1 and S2. The steps of forming this erase gate may include but are not limited to: first form a conformal cap oxide layer 137 on the substrate 100, the stack structures S1 and S2, and the select gate 131; then perform a photolithographic process to remove the portion of the cap oxide layer 137 on the inner region between the stack structures S1 and S2, so that the cap oxide layer 137 would cover only on the substrate region other than the inner region between the stack structures S1 and S2 and exposes the poly-silicon structure 133 remaining in the inner region. The cap oxide layer 137 will serve as an etch block in the following process. Since the remaining poly-silicon structure 133 has an uneven profile, a thick sacrificial poly-silicon layer 134 would be first deposited on entire substrate (including the portion of poly-silicon structure 133) before the blanket etch process, then a chemical mechanical polishing (CMP) process is performed to planarize the sacrificial poly-silicon layer 134, so that the poly-silicon layer in the inner region between the stack structures S1 and S2 becomes a flat structure. This may facilitate the formation of the erase gate structure with flat top surface.

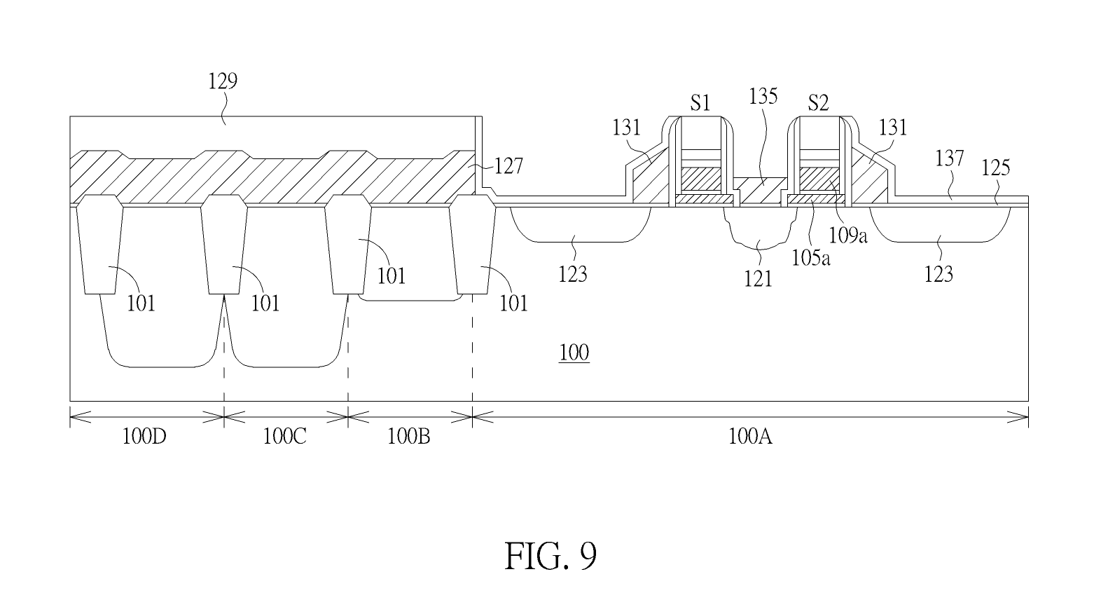

Please refer now to FIG. 9. A blanket etch-back process is performed to etch the above-mentioned planarized sacrificial poly-silicon layer 134 and the poly-silicon structure 133 in the inner region, thereby forming an erase gate 135 in the inner region with a flat top surface and a height lower than the select gate 131 and the control gate 109a. Finally, perform a photolithographic process to remove the sacrificial poly-silicon layer 134 other than the erase gate 135. The cap oxide layer 137 serves as an etch stop layer in this step. In this way, the split gate type non-volatile memory cell as shown in FIG. 9 is completed.

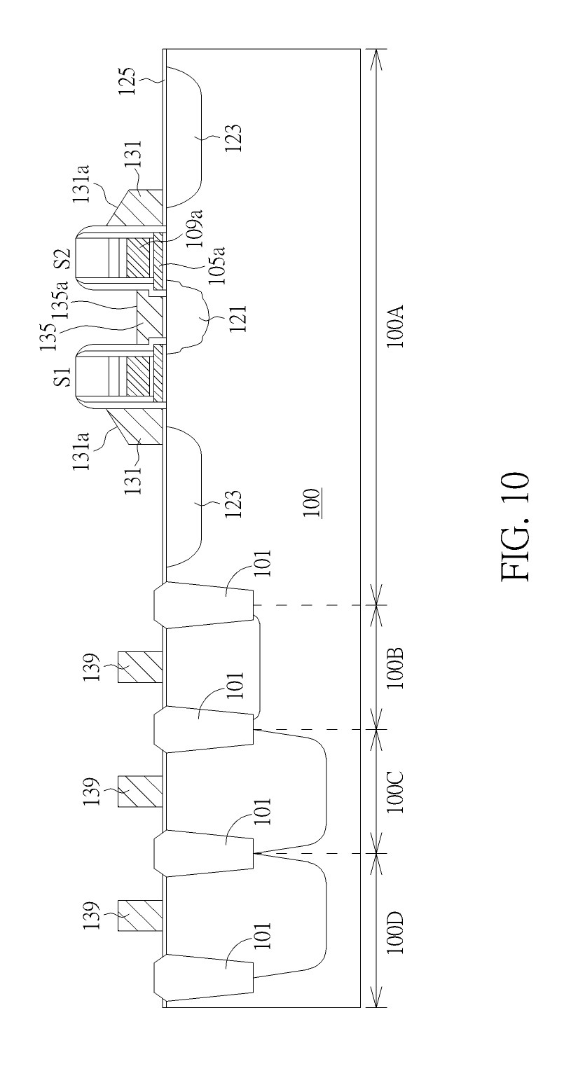

After the memory unit on the memory area 100A is made, the circuit devices on the logic areas 100B/100C/100D are then made in next the step. Please refer to FIG. 10. In the preferred embodiment of the present invention, the gate devices on the logic areas 100B/100C/100D and the select gate 131 and the control gate 135 of the memory cell on the memory area 100A are also formed from the previously deposited poly-silicon layer 127. The difference is that the gate devices on the logic areas are made in later steps. As shown in FIG. 9, first cap oxide layer 137 on the substrate and the cap oxide layer 129 on the logic areas 100B/100C/100D are removed to expose the underlying poly-silicon layer 127 in the logic areas 100B/100C/100D. A photolithographic process is then performed on the poly-silicon layer 127 to form the gate structures 139 with predetermined pattern on the logic areas 100B/100C/100D.

According to the above processes shown in FIGS. 2-10, the present invention provides a novel non-volatile memory cell. As shown in FIG. 10, the structure includes a substrate 100, an erase gate 135 having a top plane 135a disposed on the substrate 100, two floating gates 105a disposed respectively at both sides of the erase gate 135, two control gates 109a disposed respectively on the two floating gates 105a, and two select gates disposed respectively at outer sides of the two floating gates and the two control gates 109a, wherein the two select gates 131 have tilted top planes 131a which are symmetric to each other.

Those skilled in the art will readily observe that numerous modifications and alterations of the device and method may be made while retaining the teachings of the invention. Accordingly, the above disclosure should be construed as limited only by the metes and bounds of the appended claims.

1. A non-volatile memory cell, comprising:
a substrate;
two stack structures disposed on said substrate, wherein each said stack structure comprises a floating gate and a control gate on said floating gate;
an erase gate disposed on said substrate between said two stack structures, wherein said erase gate comprises a top plane; and
two select gates disposed respectively at outer sides of said two stack structures, wherein said two select gates comprise tilted top planes which are symmetric to each other.

2. The non-volatile memory cell of claim 1, further comprising a source region disposed under said erase gate in said substrate and two drain regions disposed respectively at outer sides of said two select gates in said substrate.

3. The non-volatile memory cell of claim 1, further comprising an insulating layer disposed on said two control gates.

4. The non-volatile memory cell of claim 3, wherein said insulating layer is a tri-layer of silicon oxide/silicon nitride/silicon oxide.

5. The non-volatile memory cell of claim 1, wherein the height of said select gate is higher than the height of said control gate.

6. The non-volatile memory cell of claim 1, wherein the height of said control gate is higher than the height of said erase gate.

7. A method of manufacturing a non-volatile memory cell, comprising:
providing a substrate;
forming two stack structures on said substrate, wherein each said stack structure comprises a floating gate and a control gate;
forming a conformal poly-silicon layer on said substrate and said two stack structures;
performing a blanket etch process to remove a predetermined thickness of said poly-silicon layer, thereby forming two select gates respectively at outer sides of said two control gates, wherein said two select gates comprise tilted top planes which are symmetric to each other;
forming a cap oxide layer on said substrate and said two select gates which exposes said poly-silicon layer between said two stack structures; and
performing an etch process on said poly-silicon layer between said two stack structures with said cap oxide layer as an etch mask to form an erase gate between said two control gates.

8. The method of manufacturing a non-volatile memory cell of claim 7, further comprising depositing a sacrificial poly-silicon layer on said substrate after said cap oxide layer is formed, and performing a chemical mechanical polishing process to planarize said sacrificial poly-silicon layer.

9. The method of manufacturing a non-volatile memory cell of claim 8, further comprising performing an etch process to said poly-silicon layer and said sacrificial poly-silicon layer between said two stack structures with said cap oxide layer as an etch mask to form said erase gate between said two control gates.

10. The method of manufacturing a non-volatile memory cell of claim 7, further comprising removing said cap oxide layer to expose said poly-silicon layer on a logic area after said erase gate is formed.

11. The method of manufacturing a non-volatile memory cell of claim 7, further comprising patterning said exposed poly-silicon layer to form gates on said logic area.
